(19) United States
(12) Patent Application Publication
(10) Pub. No.: US 2005/0205837 A1
(43) Pub. Date: Sep. 22, 2005

(54) Polishing composition and polishing method

(76) Inventor: Toshihiro Miwa, Aichi (JP)

Correspondence Address: VIDAS, ARRETT & STEINKRAUS, P.A., 6109 BLUE CIRCLE DRIVE, SUITE 2000, MINNETONKA, MN, 55343-9185, US

(21) Appl. No.: 11/084,415

(22) Filed: Mar. 18, 2005

(30) Foreign Application Priority Data
Mar. 19, 2004 (JP) 2004-081584

(51) Int. Cl. C09K 13/00; H01L 21/302; B44C 1/22

(52) U.S. Cl. 252/79.1; 252/79.2; 216/88; 216/89

(57) ABSTRACT

A polishing composition includes silicon dioxide, an alkaline compound, an anionic surfactant, and water. The silicon dioxide is, for example, colloidal silica, fumed silica, or precipitated silica. The alkaline compound is, for example, potassium hydroxide, sodium hydroxide, ammonia, tetramethylammonium hydroxide, piperazine anhydride, or piperazine hexahydrate. The anionic surfactant is at least one selected from a sulfonic acid surfactant, a carboxylic acid surfactant, and a sulfuric acid ester surfactant. The polishing composition can be suitably used in applications for polishing a silicon wafer.

### BACKGROUND OF THE INVENTION

The present invention relates to a polishing composition for use in polishing of a silicon wafer for a semiconductor device, and a polishing method using such a polishing composition.

Conventionally, there is known a polishing composition for use in applications for polishing a silicon wafer for a semiconductor device. Japanese Laid-Open Patent Publication No. 4-291723 discloses a polishing composition containing alkaline colloidal silica and an anionic surfactant. This prior art polishing composition is used for mirror-finishing silicon wafer surfaces, where the alkaline colloidal silica acts to mechanically polish a silicon wafer and the anionic surfactant acts to improve haze on the silicon wafer.

Recently, with semiconductor devices becoming more functional and integrated more densely, requirements to be met by a polishing composition for use in applications for polishing a silicon wafer include:
(1) after polishing with the polishing composition, the surface roughness of the silicon wafer must be small, and
(2) the polishing composition must have a high stock removal rate, i.e., the polishing composition must be highly capable of polishing a silicon wafer.

However, prior art polishing compositions do not satisfy the above requirements, and are thus susceptible to improvement.

### SUMMARY OF THE INVENTION

It is an object of the present invention to provide a polishing composition that can be suitably used in applications for polishing a silicon wafer. It is another object of the present invention to provide a polishing method using such a polishing composition.

To achieve the foregoing and other objectives and in accordance with the purposes of the present invention, the invention provides a polishing composition. The polishing composition, for use in an application for polishing a silicon wafer, contains silicon dioxide, an alkaline compound, anionic surfactant, and water. The anionic surfactant is at least one selected from a sulfonic acid surfactant, a carboxylic acid surfactant, and a sulfuric acid ester surfactant.

The invention also provides a method for polishing a silicon wafer. The method includes preparing the above polishing composition and polishing the surface of a silicon wafer, using the prepared polishing composition.

Other aspects and advantages of the invention will become apparent from the following description, illustrating by way of example the principles of the invention.

### DETAILED DESCRIPTION OF THE PREFERRED EMBODIMENTS

One embodiments of the present invention will now be described.

A silicon wafer used as a substrate for supporting a semiconductor is produced from a single-crystal silicon ingot, from which a wafer is cut off and is subject to lapping, etching and edge polishing, in this order. A silicon wafer is generally subjected to a chemical mechanical polishing (CMP) process, in which chemical polishing and mechanical polishing are combined, so as to have the surface thereof mirror-finished.

A process for polishing a silicon wafer generally comprises a preliminary polishing step for preliminarily polishing the surface of a silicon wafer and a finish polishing step for finish-polishing the surface of the preliminarily polished silicon wafer for the purpose of improving the stock removal rate as well as quality of the surface of the silicon wafer after polishing. In the preliminary polishing step, it is mainly required that the stock removal rate be high, while in the finish polishing step, it is mainly required that the surface quality of the silicon wafer after polishing be good. The preliminary polishing step may comprise a plurality of preliminary polishing sub-steps. When the preliminary polishing step comprises two preliminary polishing sub-steps, the prior preliminary polishing sub-step is required to exhibit a higher stock removal rate than the later preliminary polishing sub-step, and the later preliminary polishing sub-step is required to achieve a polished silicon wafer surface of higher quality than the prior preliminary polishing sub-step. The polishing composition according to the present embodiment is used in applications for polishing a silicon wafer, and is preferably used in applications for preliminary-polishing the surface of a silicon wafer. When the preliminary polishing step comprises a plurality of preliminary polishing sub-steps, the polishing composition according to the present embodiment is preferably used at least in the last preliminary polishing sub-step. Alternatively, polishing of a silicon wafer may be carried out in a single step using the polishing composition according to the present embodiment, instead of being carried out in a plurality of polishing steps.

A polishing composition according to the present embodiment contains silicon dioxide (silica particles), an alkaline compound, anionic surfactant, and water.

Silicon dioxide in the polishing composition acts as an abrasive for mechanically polishing a silicon wafer, which is an object to be polished. Silicon dioxide in the polishing composition may be colloidal silica, fumed silica, or precipitated silica. Among them, colloidal silica or fumed silica is preferable, and colloidal silica is more preferable, since the number of scratches left on the surface of the silicon wafer after polishing is reduced. The number of types of silicon dioxide in the polishing composition may be one or two or more.

When silicon dioxide in the polishing composition is colloidal silica, the average particle diameter D_{SA} of colloidal silica, which is found from its particle density and the specific surface area thereof determined by the BET method, is preferably 5 nm or more, since the stock removal rate of the polishing composition improves. At the same time, the average particle diameter D_{SA} of colloidal silica is preferably 300 nm or less, more preferably 200 nm or less, and most preferably 120 nm or less, since the number of scratches left on the surface of the silicon wafer after polishing is reduced and the surface roughness of the silicon wafer after polishing is also reduced. The average particle diameter D_{N4} of colloidal silica, which is determined by the laser diffraction scattering method, is preferably 5 nm or more, since the stock removal rate of the polishing composition improves. At the same time, the average particle diameter D_{N4} of colloidal silica is preferably 300 nm or less, more preferably 200 nm or less, and most preferably 150 nm or less, since the number of scratches left on the surface of the silicon wafer after polishing is reduced and the surface roughness of the silicon wafer after polishing is also reduced.

When silicon dioxide in the polishing composition is fumed silica, the average particle diameter D_{SA} of fumed silica, which is found from its particle density and the specific surface area thereof determined by the BET method, is preferably 10 nm or more, since the stock removal rate of the polishing composition improves. At the same time, the average particle diameter D_{SA} of fumed silica is preferably 300 nm or less, more preferably 200 nm or less, and most preferably 120 nm or less, since the number of scratches left on the surface of the silicon wafer after polishing is reduced and the surface roughness of the silicon wafer after polishing is also reduced. The average particle diameter D_{N4} of fumed silica, which is determined by the laser diffraction scattering method, is preferably 30 nm or more, more preferably 40 nm or more, and most preferably 50 nm or more, since the stock removal rate of the polishing composition improves. At the same time, the average particle diameter D_{N4} of fumed silica is preferably 500 nm or less, more preferably 400 nm or less, and most preferably 300 nm or less, since the number of scratches left on the surface of the silicon wafer after polishing is reduced and the surface roughness of the silicon wafer after polishing is also reduced.

It is preferred that silicon dioxide in the polishing composition contain the smallest possible amount of metallic impurities such as iron, nickel, copper, calcium, chromium or zinc. Specifically, when a water dispersion containing 20% by mass of silicon dioxide is prepared using silicon dioxide to be used for the polishing composition, the content of the metal impurities in the water dispersion is preferably 300 ppm or less, more preferably 100 ppm or less, and most preferably 0.3 ppm or less. When the content of the metallic impurities exceeds 300 ppm, the polishing composition contains a significant amount of metallic impurities derived from silicon oxide. Thus, when a silicon wafer is polished using the polishing composition, there is a risk that a significant amount of metallic impurities could adhere to the surface of the silicon wafer, and could diffuse into the silicon wafer during heat treatment after polishing, which may adversely affect electrical properties of the silicon wafer.

The content of the silicon dioxide in the polishing composition is preferably 0.1% by mass or more, more preferably 0.5% by mass or more, and most preferably 1% by mass or more, since the stock removal rate of the polishing composition improves. At the same time, the content of the silicon dioxide is preferably 50% by mass or less, more preferably 35% by mass or less, and most preferably 25% by mass or less, since excessive increase of polishing composition viscosity is inhibited and gelation of the polishing composition can be thereby inhibited.

The alkaline compound in the polishing composition chemically polishes the surface of the silicon wafer by corrosion or etching, thereby serving as a polish accelerator which supports mechanical polishing by silicon dioxide.

The alkaline compound in the polishing composition may be an inorganic alkaline compound such as potassium hydroxide, sodium hydroxide, potassium hydrogen carbonate, potassium carbonate, sodium hydrogen carbonate, and sodium carbonate; ammonia; an ammonium salt such as tetramethylammonium hydroxide, ammonium hydrogen carbonate, and ammonium carbonate; and an amine such as methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, piperazine anhydride, piperazine hexahydrate, 1-(2-aminoethyl)piperazine, and N-methylpiperazine. Among them, potassium hydroxide, sodium hydroxide, potassium hydrogen carbonate, potassium carbonate, sodium hydrogen carbonate, sodium carbonate, ammonia, tetramethylammonium hydroxide, ammonium hydrogen carbonate, ammonium carbonate, piperazine anhydride, piperazine hexahydrate, 1-(2-aminoethyl)piperazine, or N-methylpiperazine is preferable, since stock removal rate of the polishing composition is particularly improved; and potassium hydroxide, sodium hydroxide, ammonia, tetramethylammonium hydroxide, piperazine anhydride, or piperazine hexahydrate is more preferable, since contamination of the silicon wafer due to metallic impurities in the polishing composition, e.g., iron, nickel, copper, potassium, magnesium, and hydroxide and oxide thereof is prevented. The number of types of the alkaline compounds in the polishing composition may be one or two or more.

The reason that the contamination of the silicon wafer due to metallic impurities in the polishing composition is prevented when the alkaline compound in the polishing composition is potassium hydroxide, sodium hydroxide, ammonia, tetramethylammonium hydroxide, piperazine anhydride, or piperazine hexahydrate, is conceivably because no chelate bond is formed between the compound and a metal atom. An alkaline compound which can be bound to a metallic atom by a chelate bond may be bound to metallic impurities in the polishing composition by a chelate bond to form a complex ion. However, the metallic impurities are released from the complex ion during the polishing process with the polishing composition, because the bond between the alkaline compound and metal is not very strong. When the metallic impurities released from the complex ion adhere to the surface of the silicon wafer, they diffuse into the silicon wafer during the subsequent heat treatment and adversely affect electrical properties of the silicon wafer. In this regard, since potassium hydroxide, sodium hydroxide, ammonia, tetramethylammonium hydroxide, piperazine anhydride, and piperazine hexahydrate form no chelate bond with metallic impurities in the polishing composition, they should cause no problem as mentioned above.

When the alkaline compound in the polishing composition is potassium hydroxide, sodium hydroxide, tetramethylammonium hydroxide, ammonium hydrogen carbonate, ammonium carbonate, potassium hydrogen carbonate, potassium carbonate, sodium hydrogen carbonate, sodium carbonate, ammonia, methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, or triethylenetetramine, the content of the alkaline compound in the polishing composition is preferably 0.1% by mass or more, more preferably 0.5% by mass or more, and most preferably 1% by mass or more, since the stock removal rate of the polishing composition improves. At the same time, the content of the alkaline compound is preferably 6% by mass or less, more preferably 5% by mass or less, and most preferably 4% by mass or less, since the production of the roughness on the surface of the silicon wafer after polishing is inhibited, and excessive increase of polishing composition viscosity is inhibited, and gelation of the polishing composition can be thereby inhibited.

When the alkaline compound in the polishing composition is piperazine anhydride, 1-(2-aminoethyl)piperazine, or N-methylpiperazine, the content of the alkaline compound in the polishing composition is preferably 0.1% by mass or more, more preferably 1% by mass or more, and most preferably 3% by mass or more, since the stock removal rate of the polishing composition improves. At the same time, the content of the alkaline compound is preferably 10% by mass or less, more preferably 9% by mass or less, and most preferably 8% by mass or less, since the production of the roughness on the surface of the silicon wafer after polishing is inhibited, and excessive increase of the polishing composition viscosity is inhibited, and gelation of the polishing composition can be thereby inhibited.

When the alkaline compound in the polishing composition is piperazine hexahydrate, the content of the alkaline compound in the polishing composition is preferably 0.1% by mass or more, more preferably 2% by mass or more, and most preferably 5% by mass or more, since the stock removal rate of the polishing composition improves. At the same time, the content of the alkaline compound is preferably 20% by mass or less, more preferably 18% by mass or less, and most preferably 16% by mass or less, since the production of the roughness on the surface of the silicon wafer after polishing is inhibited, and excessive increase of the polishing composition viscosity is inhibited, and gelation of the polishing composition can be thereby inhibited.

The anionic surfactant in the polishing composition serves as an agent for reducing the surface roughness of the silicon wafer polished with the polishing composition. The anionic surfactant in the polishing composition is at least one selected from a sulfonic acid surfactant, a carboxylic acid surfactant, and a sulfuric acid ester surfactant. Among them, a carboxylic acid surfactant or a sulfuric acid ester surfactant is preferable, since they have a stronger action to reduce surface roughness of the silicon wafer after polishing, and they inhibit lowering of stock removal rate due to their addition.

Examples of the sulfonic acid surfactant include a sulfosuccinate such as disodium polyoxyethylene alkyl sulfosuccinate (formula (1) below), sodium coconut oil fatty acid methyltaurate (formula (2) below), alkyl sulfonate, alkyl benzene, alkyl naphthalene sulfonate, naphthalene sulfonate, α-olefin sulfonate, and N-acyl sulfonate. In formula (1) below, R represents an alkyl group of 12 to 14 carbon atoms. Examples of the carboxylic acid surfactant include sodium coconut oil fatty acid sarcosinate (formula (3) below), triethanolamine laurate (formula (4) below), soap (alkali metal salt of fatty acid), N-acyl amino acid salt, polyoxyethylene alkyl ether carboxylate, polyoxypropylene alkyl ether carboxylate, and acylated peptide. Examples of the sulfuric acid ester surfactant include an alkyl sulfate such as sodium lauryl sulfate (formula (5) below), an alkyl ether sulfate such as sodium laureth sulfate (formula (6) below), sulfated oil, polyoxyethylene alkyl allyl ether sulfate, polyoxypropylene alkyl allyl ether sulfate, and alkyl amide sulfate.
RO(CH₂CH₂O)₃COCH₂CH(SO₃Na)COONa (1)
C₁₂H₂₅CON(CH₃)CH₂CH₂SO₃Na (2)
C₁₂H₂₅CON(CH₃)CH₂COONa (3)
C₁₂H₂₅COON(CH₂CH₂OH)₃ (4)
C₁₂H₂₅OSO₃Na (5)
C₁₂H₂₅O(CH₂CH₂O)₃SO₃Na (6)

The content of the anionic surfactant in the polishing composition is preferably 0.00008% by mass or more, more preferably 0.0008% by mass or more, and most preferably 0.004% by mass or more, since the surface roughness of the silicon wafer after polishing is reduced. At the same time, the content of the anionic surfactant is preferably 1.6% by mass or less, more preferably 0.16% by mass or less, and most preferably 0.016% by mass or less, since excessive increase of polishing composition viscosity is inhibited and gelation of the polishing composition can be thereby inhibited.

Water in the polishing composition serves to dissolve or disperse therein other components in the polishing composition. It is preferred that the water contain the smallest possible amount of impurities so as not to disturb other components. Specifically, pure water treated with ion-exchanging resin to remove impurity ions and subsequently filtered to remove foreign matter, ultrapure water or distilled water is preferable.

The polishing composition may further contain a chelating agent, which reacts with metallic impurities in the polishing composition to form a complex ion and thereby plays a role in capturing metal impurities in the polishing composition.

Examples of the chelating agents include acids, such as nitrilotriacetic acid, ethylenediamine tetraacetic acid, hydroxyethylenediamine tetraacetic acid, propanediamine tetraacetic acid, diethylenetriamine pentaacetic acid, triethylenetetramine hexaacetic acid, ethylenediamine tetraethylene phosphonic acid, ethylenediamine tetramethylene phosphonic acid, ethylenediamine tetrakismethylene phosphonic acid, diethylenetriamine pentaethylene phosphonic acid, diethylenetriamine pentamethylene phosphonic acid, triethylenetetramine hexaethylene phosphonic acid, triethylenetetramine hexamethylene phosphonic acid, propanediamine tetraethylene phosphonic acid, propanediamine tetramethylene phosphonic acid; and a kind of salt selected from these acids. Examples of the salt include ammonium salt, potassium salt, sodium salt, and lithium salt.

The polishing composition may further contain if required a surfactant in addition to the above-mentioned anionic surfactant, a thickening agent, an emulsifier, a preservative, a rust-inhibitor, a defoaming agent or the like.

The polishing composition according to the present embodiment may be provided for use after dilution with water, or without dilution. When the polishing composition is diluted with water, the dilution rate (ratio by volume) is preferably 50 times or less, more preferably 30 times or less, and most preferably 20 times or less.

The present embodiment has the following advantages.

A polishing composition according to the present embodiment containing an anionic surfactant, which is at least one selected form a sulfonic acid surfactant, a carboxylic acid surfactant, and a sulfuric acid ester surfactant as an agent for reducing surface roughness, can reduce the surface roughness of the silicon wafer after polishing. This is presumably due to the following reason.

The surfaces of the silicon dioxide (silica particle) are charged slightly negatively, which generates a weak electrostatic repulsive force between them. A sulfonic acid surfactant, a carboxylic acid surfactant, and a sulfuric acid ester surfactant are also charged negatively, which generate an electrostatic repulsive force not only between the silica particles themselves but also between the silica particles and surfactant, enhancing dispersibility of the silica particles in the polishing composition while inhibiting their agglomeration. It is therefore believed that increase of the surface roughness of the polished silicon wafer, resulting from the agglomerated silicon dioxide, is inhibited. As an example of an anionic surfactant, a phosphoric acid surfactant can also be mentioned in addition to a sulfonic acid surfactant, a carboxylic acid surfactant, and a sulfuric acid ester surfactant. However, the surface roughness of the polished silicon wafer may not be sufficiently reduced with a phosphoric acid surfactant. This is presumably because a phosphoric acid surfactant cannot enhance dispersibility of the silica particles.

Next, examples and comparative examples of the present invention will be described.

Stock solutions for polishing compositions according to Examples 1 to 20 and Comparative Examples 1 to 8 were prepared by adding if required an abrasive, surfactant, alkaline compound, and chelating agent to ultrapure water. Table 1 provides the details of the abrasive, surfactant, alkaline compound, and chelating agent in each stock solution. Each stock solution was diluted with ultrapure water at a ratio (ratio by volume) of twenty to one to prepare the polishing compositions according to Examples 1 to 20 and Comparative Examples 1 to 8.

The surface of a silicon wafer was polished using each of the polishing compositions on the polishing conditions mentioned below. Thickness of the silicon wafer before polishing and the thickness of the polished silicon wafer after washing by ultrapure water was measured using a “DIGIMATIC INDICATOR” manufactured by Mitutoyo Corporation. Each of the polishing compositions was rated on a scale of one to four according to the stock removal rate for the silicon wafer, calculated by the below-mentioned formula: Very good (1); Good (2); Acceptable (3); and Unacceptable (4). Specifically, the polishing composition was rated very good when the stock removal rate was 0.4 μm/minute or more; it was rated good when the stock removal rate was 0.3 μm/minute or more and less than 0.4 μm/minute; it was rated acceptable when the stock removal rate was 0.2 μm/minute or more and less than 0.3 μm/minute; it was rated unacceptable when the stock removal rate was less than 0.2 μm/minute. Table 1 also provides the obtained stock removal rates and the rating results in the “Stock removal rate” column.

<Polishing Condition>

Polishing machine: Single-sided polishing machine (3 pieces/plate), manufactured by Engis Corporation (Japan).
Turntable size: 380 mm in diameter
Polishing pressure: 38.7 kPa
Turntable rotation speed: 60 revolution/minute
Head rotation speed: 40 revolution/minute
Object to be polished: 32 mm square silicon wafer (p-type, crystal orientation: <100>, resistivity: 0.1 Ω·cm or more but less than 100 Ω·cm)
Polishing pad: Foamed urethane type polishing pad “MH Pad S-15”, manufactured by Rodel Inc.
Polishing time: 20 minutes
Polishing composition temperature: 20° C.
Polishing composition supplied speed: 80 ml/minute (throwaway)<
   Calculation Formula>
   Stock removal rate [μm/minute]=(thickness of silicon wafer before polishing [μm]−thickness of silicon wafer after polishing [μm])÷polishing time [minute]

A polished silicon wafer washed with ultrapure water was allowed to dry naturally and sufficiently, and the surface roughness Ra of the silicon wafer after drying naturally was measured using a “RST plus” manufactured by WYKO Corporation, (measurement range: 0.9 mm×1.2 mm, measurement magnification: 5 times). Each of the polishing compositions were rated on a scale of one to four according to the measured surface roughness Ra: Very good (1); Good (2); Slightly poor (3); Poor (4). Specifically, the polishing composition was rated very good when the surface roughness Ra was less than 0.80 nm; it was rated good when the surface roughness Ra was 0.80 nm or more and less than 0.90 nm; it was rated slightly poor when the surface roughness Ra was 0.90 nm or more and less than 1.00 nm; it was rated poor when the surface roughness Ra was 1.00 nm or more. Table 1 provides the measured surface roughness Ra and the rating results in the “Surface roughness” column. It was found that the silicon wafer had a mirror-finished surface when polished with the polishing composition prepared in each of Examples 1 to 20, and Comparative Examples 1, 2, 5 and 6, and could be measured for its surface roughness Ra, whereas the surface roughness Ra of the silicon wafer polished with the polishing composition prepared in each of Comparative Examples 3, 4, 7 and 8 could not be measured for its surface roughness Ra because their surfaces were not mirror-finished.

TABLE 1

| | | | | | Stock | Surface |
|---|---|---|---|---|---|---|
| | Abrasive | Surfactant | Alkali compound | Chelating agent | removal rate | roughness |
| | [mass percentage] | [mass percentage] | [mass percentage] | [mass percentage] | [μm/min] | [nm] |
| Ex. 1 | colloidal silica*¹ | A1 | B1 | — | 1 | 2 |
| | 17.7% | 0.008% | 1.6% | | 0.43 | 0.84 |
| Ex. 2 | colloidal silica*¹ | A2 | B1 | — | 1 | 2 |
| | 17.7% | 0.008% | 1.6% | | 0.41 | 0.83 |
| Ex. 3 | colloidal silica*¹ | A3 | B1 | — | 1 | 2 |
| | 17.7% | 0.008% | 1.6% | | 0.42 | 0.83 |
| Ex. 4 | colloidal silica*¹ | A4 | B1 | — | 1 | 2 |
| | 17.7% | 0.008% | 1.6% | | 0.44 | 0.87 |
| Ex. 5 | colloidal silica*¹ | A5 | B1 | — | 1 | 2 |
| | 17.7% | 0.008% | 1.6% | | 0.41 | 0.84 |
| Ex. 6 | coLloidal silica*¹ | A6 | B1 | — | 1 | 2 |
| | 17.7% | 0.008% | 1.6% | | 0.41 | 0.83 |
| Ex. 7 | colloidal silica*¹ | A1 | B1 | — | 3 | 2 |
| | 17.7% | 0.08% | 1.6% | | 0.26 | 0.81 |
| Ex. 8 | colloidal silica*¹ | A1 | B1 | — | 3 | 1 |
| | 17.7% | 0.8% | 1.6% | | 0.24 | 0.72 |
| Ex. 9 | colloidal silica*² | A1 | B1 | — | 1 | 2 |
| | 17.7% | 0.008% | 1.6% | | 0.42 | 0.85 |
| Ex. 10 | colloidal silica*¹ | A1 | B1 | — | 1 | 2 |
| | 8.9% | 0.008% | 1.6% | | 0.43 | 0.85 |
| Ex. 11 | colloidal silica*¹ | A1 | B1 | — | 1 | 2 |
| | 35% | 0.008% | 1.6% | | 0.43 | 0.84 |
| Ex. 12 | colloidal silica*¹ | A1 | B2 | — | 1 | 2 |
| | 17.7% | 0.008% | 1.6% | | 0.47 | 0.88 |
| Ex. 13 | colloidal silica*¹ | A1 | B3 | — | 1 | 2 |
| | 17.7% | 0.008% | 1.6% | | 0.47 | 0.88 |
| Ex. 14 | colloidal silica*¹ | A1 | B4 | — | 2 | 2 |
| | 17.7% | 0.008% | 1.6% | | 0.35 | 0.8 |
| Ex. 15 | colloidal silica*¹ | A1 | B5 | — | 2 | 2 |
| | 17.7% | 0.008% | 1.6% | | 0.35 | 0.8 |
| Ex. 16 | colloidal silica*¹ | A1 | B1 | — | 1 | 2 |
| | 17.7% | 0.008% | 0.8% | | 0.43 | 0.84 |
| Ex. 17 | colloidal silica*¹ | A1 | B1 | — | 1 | 2 |
| | 17.7% | 0.008% | 1.2% | | 0.42 | 0.83 |
| Ex. 18 | colloidal silica*¹ | A1 | B1 | — | 1 | 2 |
| | 17.7% | 0.008% | 3.2% | | 0.44 | 0.85 |
| Ex. 19 | colloidal silica*¹ | A1 | B1 | D1 | 1 | 2 |
| | 17.7% | 0.008% | 1.6% | 0.24% | 0.43 | 0.84 |
| Ex. 20 | colloidal silica*¹ | A1 | B1 | D2 | 1 | 2 |
| | 17.7% | 0.08% | 1.6% | 0.24% | 0.44 | 0.85 |
| C. Ex. 1 | colloidal silica*¹ | — | B1 | — | 1 | 3 |
| | 17.7% | | 1.6% | | 0.46 | 0.92 |
| C. Ex. 2 | colloidal silica*¹ | E1 | B1 | — | 3 | 4 |
| | 17.7% | 0.008% | 1.6% | | 0.21 | 1.20 |
| C. Ex. 3 | colloidal silica*¹ | E2 | B1 | — | 4 | — |
| | 17.7% | 0.008% | 1.6% | | 0.05 | |
| C. Ex. 4 | colloidal silica*¹ | E3 | B1 | — | 4 | — |
| | 17.7% | 0.008% | 1.6% | | 0.03 | |
| C. Ex. 5 | colloidal silica*¹ | E4 | B1 | — | 1 | 3 |
| | 17.7% | 0.008% | 1.6% | | 0.46 | 0.91 |
| C. Ex. 6 | colloidal silica*¹ | E5 | B1 | — | 1 | 3 |
| | 17.7% | 0.008% | 1.6% | | 0.46 | 0.93 |
| C. Ex. 7 | — | A1 | B1 | — | 4 | — |
| | | 0.008% | 1.6% | | 0.18 | |
| C. Ex. 8 | colloidal silica*¹ | A1 | — | — | 4 | — |
| | 17.7% | 0.008% | | | 0.10 | |

In the “Abrasive” column in Table 1:
“colloidal silica*¹” is colloidal silica having an average particle diameter D_{N4} of 70 nm and an average particle diameter D_{SA} of 35 nm; and
“colloidal silica*²” is colloidal silica having an average particle diameter D_{N4} of 26 nm and an average particle diameter D_{SA} of 12 nm. The average particle diameter D_{N4} was measured by using an N4 Plus Submicron Particle Sizer, manufactured by Beckman Coulter Inc. and the average particle diameter D_{SA} was found from specific surface area measurements using a “FlowSorbII2300”, manufactured by Micromeritics Instrument Corporation. The colloidal silica to be used in each polishing composition was dispersed in water to 20% by mass, and the water dispersion contained iron, nickel, copper, calcium, chromium and zinc each at 20 ppb or less.

In the “Surfactant column” in Table 1:
“A1” represents sodium lauryl sulfate as a sulfuric acid ester surfactant;
“A2” represents sodium laureth sulfate as a sulfuric acid ester surfactant;
“A3” represents disodium polyoxyethylene alkyl (12 to 14) sulfosuccinate as a sulfonic acid surfactant;
“A4” represents sodium coconut oil fatty acid methyltaurate as a sulfonic acid surfactant;
“A5” represents sodium coconut oil fatty acid sarcosinate as a carboxylic acid surfactant;
“A6” represents triethanolamine laurate as a carboxylic acid surfactant;
“E1” represents polyoxyethylene alkyl (12 to 15) ether phosphoric acid as a phosphoric acid ester surfactant;
“E2” represents polyoxyethylene sorbitan monolaurate (20E0) as a nonionic surfactant;
“E3” represents polyoxyethylene sorbitan monooleate (20E0) as a nonionic surfactant;
“E4” represents hydroxyethyl cellulose (molecular weight: 1,600,000, viscosity: 2000 to 3000 mPa·S) as a nonionic surfactant; and
“E5” represents polyvinyl alcohol (average degree of polymerization: 550, degree of saponification: 88%) as a nonionic surfactant.

Each of the anionic surfactants A1 to A6 and E1 was composed of a plurality of different surfactants whose alkyl groups had 10 to 16 carbon atoms, and each of the anionic surfactants had as its main component a surfactant whose alkyl groups had 12 carbon atoms. Here, “main component” means that the content (% by mass) of the component is the highest in the plurality of surfactants.

In the “Alkali compound” column in Table 1:
“B1” represents tetramethyl ammonium hydroxide;
“B2” represents piperazine hexahydrate;
“B3” represents piperazine anhydride;
“B4” represents potassium hydroxide; and
“B5” represents sodium hydroxide.

In the “Chelating agent” column in Table 1:
“D1” represents ethylene diamine tetraethylene phosphonic acid; and
“D2” represents triethylene tetramine hexaacetate.

As shown in Table 1, the polishing composition prepared in each of Examples 1 to 20 was rated “Very good”, “Good”, or “Acceptable” with respect to both “Stock removal rate” and “Surface roughness”. This result suggests that the polishing compositions according to Examples 1 to 20 are useful in an application for polishing a silicon wafer. The results of Examples 1, 7 and 8 show that the surface roughness Ra can be reduced notably by setting the content of the anionic surfactant in the polishing composition at 0.08% by mass or more, more specifically at 0.8% by mass or more.

The results of Comparative Examples 1, 2, 5 and 6 show that the silicon wafer has an increased surface roughness Ra when polished with a polishing composition that does not contain a sulfonic acid surfactant, a carboxylic acid surfactant, or a sulfuric acid ester surfactant. The results of Comparative Examples 3 and 4 show that the stock removal rate deteriorates and a mirror-finish of the silicon wafer surface cannot be achieved when polished with a composition-containing polyoxyethylene sorbitan monolaurate or polyoxyethylene sorbitan monooleate in place of a sulfonic acid surfactant, a carboxylic acid surfactant, or a sulfuric acid ester surfactant. The results of Comparative Examples 7 and 8 show that the stock removal rate deteriorates and a mirror-finish of the silicon wafer surface cannot be achieved when polished with a composition that does not a colloidal silica or alkaline compound.

1. A polishing composition for use in an application for polishing a silicon wafer, the polishing composition comprising silicon dioxide, an alkaline compound, anionic surfactant, and water, wherein the anionic surfactant is at least one selected from a sulfonic acid surfactant, a carboxylic acid surfactant, and a sulfuric acid ester surfactant.

2. The polishing composition according to claim 1, wherein the silicon dioxide is colloidal silica, fumed silica, or precipitated silica.

3. The polishing composition according to claim 2, wherein the silicon dioxide is colloidal silica.

4. The polishing composition according to claim 3, wherein the colloidal silica has an average particle diameter of 5 to 300 nm based on particle density of the colloidal silica and specific surface area of the colloidal silica as determined by a BET method.

5. The polishing composition according to claim 3, wherein the colloidal silica has an average particle diameter of 5 to 300 nm as determined by a laser diffraction scattering method.

6. The polishing composition according to claim 2, wherein the silicon dioxide is fumed silica having an average particle diameter of 10 to 300 nm based on particle density of the fumed silica and specific surface area of the fumed silica as determined by a BET method.

7. The polishing composition according to claim 2, wherein the silicon dioxide is fumed silica having an average particle diameter of 30 to 500 nm as determined by a laser diffraction scattering method.

8. The polishing composition according to claim 1, wherein content of the silicon dioxide in the polishing composition is 0.1 to 50% by mass.

9. The polishing composition according to claim 8, wherein content of the silicon dioxide in the polishing composition is 1 to 25% by mass.

10. The polishing composition according to claim 1, wherein the alkaline compound is potassium hydroxide, sodium-hydroxide, potassium hydrogen carbonate, potassium carbonate, sodium hydrogen carbonate, sodium carbonate, ammonia, tetramethylammonium hydroxide, ammonium hydrogen carbonate, ammonium carbonate, methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, piperazine anhydride, piperazine hexahydrate, 1-(2-aminoethyl)piperazine, or N-methylpiperazine.

11. The polishing composition according to claim 10, wherein the alkaline compound is potassium hydroxide, sodium hydroxide, ammonia, tetramethylammonium hydroxide, piperazine anhydride, or piperazine hexahydrate.

12. The polishing composition according to claim 1, wherein the anionic surfactant is a carboxylic acid surfactant or a sulfuric acid ester surfactant.

13. The polishing composition according to claim 1, wherein the sulfonic acid surfactant is a sulfosuccinate, sodium coconut oil fatty acid methyltaurate-, alkyl sulfonate, alkyl benzene, alkyl naphthalene sulfonate, naphthalene sulfonate, α-olefin sulfonate, or N-acyl sulfonate.

14. The polishing composition according to claim 1, wherein the carboxylic acid surfactant is sodium coconut oil fatty acid sarcosinate, triethanolamine laurate, soap, N-acyl amino acid salt, polyoxyethylene alkyl ether carboxylate, polyoxypropylene alkyl ether carboxylate, or acylated peptide.

15. The polishing composition according to claim 1, wherein the sulfuric acid ester surfactant is an alkyl sulfate, alkyl ether sulfate, sulfated oil, polyoxyethylene alkyl allyl ether sulfate, polyoxypropylene alkyl allyl ether sulfate, or alkyl amide sulfate.

16. The polishing composition according to claim 1, wherein content of the anionic surfactant is 0.00008 to 1.6% by mass.

17. The polishing composition according to claim 16, wherein content of the anionic surfactant is 0.004 to 0.016% by mass.

18. A method for polishing a silicon wafer, the method comprising:
preparing a polishing composition containing silicon dioxide, an alkaline compound, an anionic surfactant and water, wherein the anionic surfactant is at least one selected from a sulfonic acid surfactant, a carboxylic acid surfactant, and a sulfuric acid ester surfactant; and
polishing the surface of a silicon wafer, using the prepared polishing composition.

19. The method according to claim 18, wherein said polishing the surface of a silicon wafer includes:
preliminarily polishing the surface of a silicon wafer; and
finish polishing the surface of the preliminarily polished silicon wafer, wherein
the polishing composition is used in said preliminarily polishing the surface of a silicon wafer.

20. The method according to claim 18, wherein said preparing a polishing composition comprises diluting the polishing composition with water.
